(19) United States
(12) Patent Application Publication
(10) Pub. No.: US 2026/0182264 A1
(43) Pub. Date: Jun. 25, 2026

(54) METHOD FOR INSPECTING GALLIUM NITRIDE BASED SEMICONDUCTOR FILM, METHOD FOR MANUFACTURING GALLIUM NITRIDE BASED SEMICONDUCTOR DEVICE COMPRISING THE SAME, AND LAYERED STRUCTURE USED THEREFOR

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 19/414,616

(22) Filed: Dec. 10, 2025

(30) Foreign Application Priority Data
Dec. 20, 2024 (JP) 2024-225796

(51) Int. Cl. H10P 14/20; G01N 21/21; G01N 21/65; G01N 21/84; G01N 21/95; G01N 23/20058; G01N 23/2251

(52) U.S. Cl. CPC H10P 14/3416; G01N 21/9501; G01N 21/211; G01N 21/65; G01N 2021/8477; G01N 23/20058; G01N 23/2251

(57) ABSTRACT

A method for inspecting a gallium nitride based semiconductor film includes preparing a layered structure including a substrate and a crystal orientation region and a crystalline region disposed on the substrate, forming a gallium nitride based semiconductor film on each of the crystal orientation region and the crystalline region, and evaluating a crystallinity of each of the gallium nitride based semiconductor films formed on the crystal orientation region and the crystalline region.

### CROSS-REFERENCE TO RELATED APPLICATIONS

This application claims the benefit of priority to Japanese Patent Application No. 2024-225796, filed on Dec. 20, 2024, the entire contents of which are incorporated herein by reference.

### FIELD

An embodiment of the present invention relates to a method for inspecting a gallium nitride based semiconductor film, a method for manufacturing a gallium nitride based semiconductor device including the same, and a layered structure used therefor.

### BACKGROUND

A gallium nitride (GaN) based semiconductor is characterized as a direct-transition semiconductor with a large bandgap. Using the characteristics of the gallium nitride based semiconductor, a light-emitting diode (LED) using the gallium nitride based semiconductor has already been put into practical use. In addition, the gallium nitride based semiconductor also has high electron saturation mobility and withstand voltage. In recent years, a transistor for use in a high-frequency power device has been developed by utilizing the characteristics of the gallium nitride based semiconductor. A gallium nitride based semiconductor film of the light-emitting diode or transistor is generally deposited on a sapphire substrate at a high temperature of 800° C. to 1000° C. using MOCVD (Metal Organic Chemical Vapor Deposition) or HVPE (Hydride Vapor Phase Epitaxy).

Further, a method for depositing the gallium nitride based semiconductor film at a low temperature includes, for example, sputtering. In sputtering, for example, a gallium nitride based semiconductor with good crystallinity can be obtained by preparing a structure in which a crystal orientation layer for improving the crystal growth of the gallium nitride based semiconductor is disposed on a substrate, and depositing the gallium nitride based semiconductor on the crystal orientation layer.

### SUMMARY

A method for inspecting a gallium nitride based semiconductor film according to an embodiment of the present invention includes preparing a layered structure including a substrate and a crystal orientation region and a crystalline region disposed on the substrate, forming a gallium nitride based semiconductor film on each of the crystal orientation region and the crystalline region, and evaluating a crystallinity of each of the gallium nitride based semiconductor films formed on the crystal orientation region and the crystalline region.

A method for manufacturing a gallium nitride based semiconductor device according to an embodiment of the present invention includes preparing a layered structure including a substrate and a crystal orientation region and a crystalline region disposed on the substrate, forming a gallium nitride based semiconductor film on each of the crystal orientation region and the crystalline region, and evaluating a crystallinity of each of the gallium nitride based semiconductor films formed on the crystal orientation region and the crystalline region.

A layered structure according to an embodiment of the present invention includes a substrate, and a crystal orientation region and a crystalline region disposed on the substrate, a gallium nitride based semiconductor film is formed on each of the crystal orientation region and the crystalline region.

### BRIEF DESCRIPTION OF DRAWINGS

FIG. 1 is a perspective view schematically showing a layered structure used in a method for inspecting a gallium nitride based semiconductor film according to an embodiment of the present invention.

FIG. 2 is a plan view showing an overview of a layered structure used for a method for inspecting a gallium nitride based semiconductor film according to an embodiment of the present invention.

FIG. 3 is a flowchart showing a method for inspecting a gallium nitride based semiconductor film according to an embodiment of the present invention.

FIG. 4 is a flowchart showing steps of preparing a layered structure according to an embodiment of the present invention.

FIG. 5 is a plan view showing a gallium nitride based semiconductor film formed in a layered structure according to an embodiment of the present invention.

FIG. 6 is a flowchart showing steps for evaluating the crystallinity of a gallium nitride based semiconductor film according to an embodiment of the present invention.

### DESCRIPTION OF EMBODIMENTS

Hereinafter, embodiments of the present invention will be described with reference to the drawings. The width, thickness, shape, and the like of each part may be schematically represented in comparison with the actual embodiments in order to clarify the description, but the drawings are merely examples and do not limit the interpretation of the present invention. In the present specification and the drawings, the same reference signs are given to elements similar to those described with respect to the drawings described previously, and a detailed description may be omitted as appropriate.

### Layered Structure

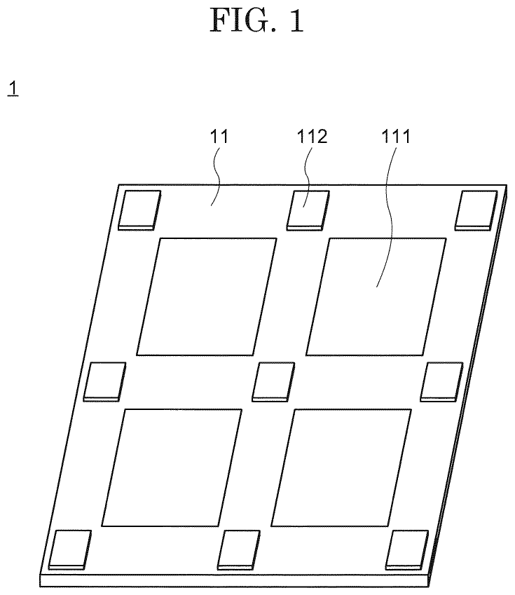

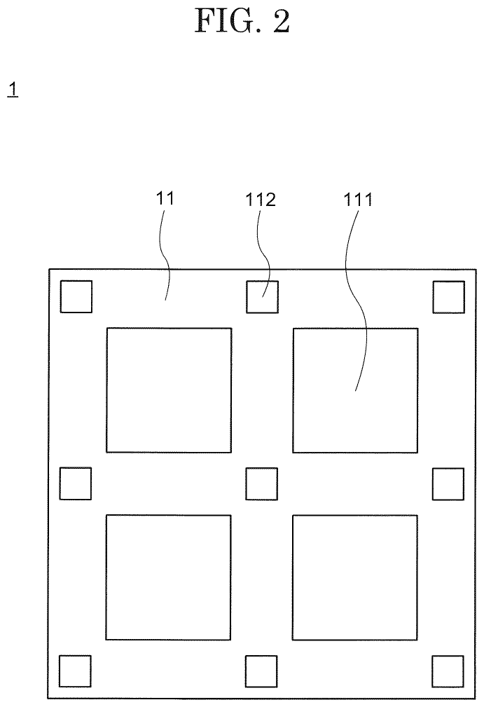

A layered structure used for a method for inspecting a gallium nitride based semiconductor film according to an embodiment of the present invention will be described. FIG. 1 is a perspective view schematically showing a layered structure 1. FIG. 2 is a plan view schematically showing the layered structure 1. As shown in FIG. 1 and FIG. 2, the layered structure 1 includes a substrate 11 and a crystal orientation region 111 and a crystalline region 112 disposed on the substrate 11.

As shown in FIG. 2, for example, the substrate 11 has a square shape in a plan view. The shape of the substrate 11 is not limited to this. For example, the size of the substrate 11 is set to be between 400 mm or more and 3440 mm or less in length, 320 mm or more and 3100 mm or less in width, in a plan view.

For example, a material that can withstand a temperature (for example, about 600° C.) when sputtering the gallium nitride based semiconductor is preferable as the substrate 11. Examples of the substrate 11 material include amorphous glass and polymer resins. Examples of the polymer resin include a polyimide resin, an acrylic resin, a siloxane resin, and a fluororesin.

As shown in FIG. 2, for example, the crystal orientation region 111 has a square shape in a plan view. The shape of the crystal orientation region 111 is not limited to this. For example, the shape and size of the crystal orientation region 111 are appropriately set depending on the application (active area, drive circuit area) of the crystal orientation region 111. The size of the crystal orientation region 111 can be made larger than the crystalline region 112 described below in a plan view. In FIG. 2, although four crystal orientation regions 111 are arranged on the substrate 11 at predetermined intervals, the number and arrangement of the crystal orientation regions 111 are not limited to this. By forming a gallium nitride based semiconductor film 113 on the crystal orientation region 111, the crystallinity of the gallium nitride based semiconductor film 113, that is, the orientation of the c-axis, can be improved.

The crystal orientation region 111 can be disposed on the substrate 11 by forming a crystal orientation film on the substrate 11. For example, the crystal orientation film is formed on the substrate 11 by sputtering or CVD. Depending on how the crystal orientation film is formed on the substrate 11, the crystallinity of the formed crystal orientation film may not be high. If the crystallinity of the crystal orientation film is not high, the crystallinity of the gallium nitride based semiconductor film 113 formed thereon is not high.

Examples of the crystal orientation film include a hexagonal close-packed structure, a face-centered cubic structure, or a structure similar thereto. The structure similar to a hexagonal close-packed structure or a face-centered cubic structure refers to a structure including a crystal structure in which the c-axis does not form 90° with respect to the a-axis and the b-axis. Examples of the material of the crystal orientation film include titanium (Ti), titanium nitride (TiNₓ), titanium oxide (TiOₓ), graphene, zinc oxide (ZnO), magnesium diboride (MgB₂), aluminum (Al), aluminum nitride (AlN), aluminum oxide (Al₂O₃), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), lithium niobate (LiNbO), BiLaTiO, SrFeO, BiFeO, BaFeO, ZnFeO, PMnN—PZT, or biological apatite (BAp). The crystal orientation film is preferably titanium, graphene, zinc oxide, aluminum nitride, or aluminum oxide.

As shown in FIG. 2, for example, the crystalline region 112 has a square shape in a plan view. The shape of the crystalline region 112 is not limited to this. For example, the size of the crystalline region 112 is set to be between 1 mm or more and 20 mm or less in length, and 1 mm or more and 20 mm or less in width, in a plan view. As shown in FIG. 2, the crystalline region 112 is disposed on the substrate 11 not to overlap the crystal orientation region 111. In FIG. 2, although nine crystalline regions 112 are disposed on the substrate 11 at positions corresponding to corner portions of the crystal orientation region 111 at predetermined intervals, the number and arrangement of the crystalline region 112 is not limited to this. By forming the gallium nitride based semiconductor film 113 on the crystalline region 112, the crystallinity of the gallium nitride based semiconductor film 113, that is, the orientation of the c-axis, can be improved.

The crystalline region 112 can be disposed on the substrate 11 by bonding a crystalline substrate on the substrate 11. The crystalline substrate refers to a single-crystal substrate or a highly crystalline polycrystalline substrate. In addition, “highly crystalline” means that the full width at half maximum (FWHM) of a diffraction peak is sufficiently small in the X-ray diffraction pattern obtained by X-ray diffraction. The crystallinity of the crystalline region 112 has a height greater than or equal to the crystallinity of the crystal orientation region 111. For example, the bonding of the crystalline substrate on the substrate 11 may include melt bonding, solid-state bonding using electrostatic attraction, surface-activated bonding, bonding using an adhesive or sticky material, and fitting to the substrate 11. In the melt bonding, Transient Liquid Phase Diffusion Bonding (TLP bonding) can be performed by providing an intermediate layer between the substrate 11 and the crystalline substrate. The bonding of the crystalline substrate on the substrate 11 can be performed by combining these methods. The bonding of the crystalline substrate on the substrate 11 may be performed individually or simultaneously using a known device.

Examples of the single-crystal substrate include a silicon substrate, a sapphire substrate, a gallium nitride substrate, a gallium nitride template (obtained by forming gallium nitride on a sapphire substrate by MOCVD method), a SAM substrate, an aluminum nitride substrate, a silicon carbide substrate, a germanium substrate, boron nitride, and graphene. In the X-ray diffraction pattern obtained by X-ray diffraction, the height of crystallinity (orientation of the c-axis) is determined by the peak of (111) for the silicon substrate, the peak of (006) for the sapphire substrate, and the peak of (002) for the gallium nitride substrate. Examples of the highly crystalline polycrystalline substrate include a titanium substrate, a zirconium substrate, a scandium substrate, and a hafnium substrate. A material of the crystalline region 112 and the crystal orientation region 111 may be the same. Since the single-crystal substrate or the highly crystalline polycrystalline substrate has high crystallinity, the crystallinity of the gallium nitride based semiconductor film 113 formed thereon is high as long as sputtering is not defective.

### Method for Inspecting Gallium Nitride Based Semiconductor Film

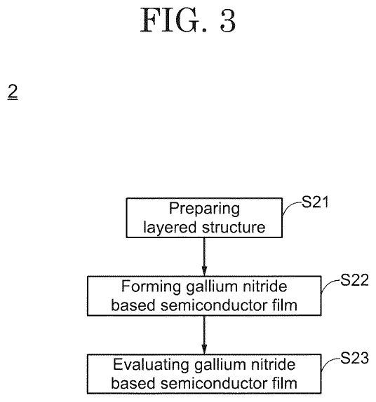

A method for inspecting a gallium nitride based semiconductor film according to an embodiment of the present invention will be described. FIG. 3 is a flowchart showing a method 2 for inspecting a gallium nitride based semiconductor film. As shown in FIG. 3, the method 2 for inspecting the gallium nitride based semiconductor film includes preparing the layered structure 1 (S21), forming the gallium nitride based semiconductor film 113 on the layered structure 1 (S22), and evaluating the crystallinity of the formed gallium nitride film 13 (S23).

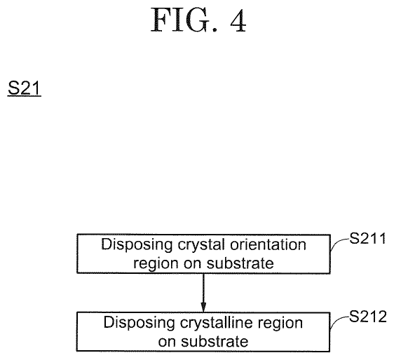

The step S21 is to prepare the layered structure 1 including the substrate 11 and the crystal orientation region 111 and the crystalline region 112 arranged on the substrate 11. FIG. 4 is a flowchart of preparing the layered structure 1. As shown in FIG. 4, preparing the layered structure 1 (S21) includes disposing the crystal orientation region 111 on the substrate 11 by forming the crystal orientation film on the substrate 11 (S211), and disposing the crystalline region 112 on the substrate 11 by bonding the crystalline substrate previously found to be highly crystalline on the substrate 11 (S212). The step S212 may be performed before the step S211, and the order of the step S211 and the step S212 is not limited.

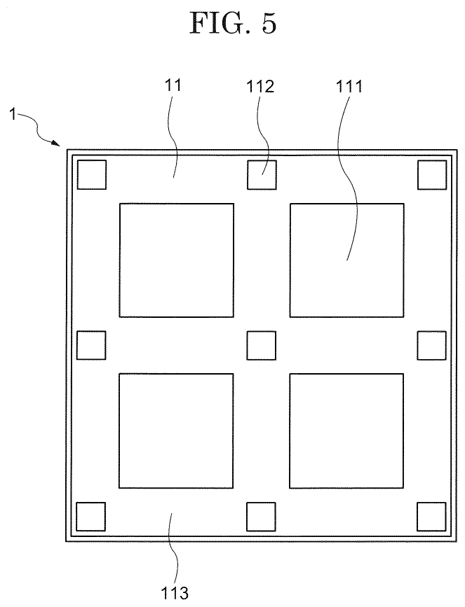

The step S22 is to form the gallium nitride based semiconductor film 113 on each of the crystal orientation region 111 and the crystalline region 112 in the layered structure 1. FIG. 5 is a plan view when the gallium nitride based semiconductor film 113 is formed on the layered structure 1. As shown in FIG. 5, the gallium nitride based semiconductor film 113 is formed on a region where the crystal orientation region 111, the crystalline region 112, and a region other than the crystal orientation region 111 and the crystalline region 112 are formed on the substrate 11. For example, the gallium nitride based semiconductor film 113 may be formed by sputtering. Examples of the sputtering target include AlₓGa₁₋ₓN, InₓGa₁₋ₓN. In the case of AlₓGa₁₋ₓN, x is preferably 0.5 or less, more preferably 0.2 or less. In the case of InₓGa₁₋ₓN, x is preferably 0.9 or less, more preferably 0.7 or less. x may be 0.

The step S23 is to evaluate the crystallinity of each of the gallium nitride based semiconductor films 113 formed on the crystal orientation region 111 and the crystalline region 112. For example, evaluating the crystallinity of the gallium nitride based semiconductor film 113 includes X-ray diffraction, ellipsometry, electron backscatter diffraction (EBSD), Raman spectroscopy, and electron diffraction.

In the X-ray diffraction, for example, the crystallinity is evaluated based on whether the FWHM of a peak at a predetermined diffraction angle exceeds a certain value (1000 arc sec or the like) from a relationship between the diffraction angle and diffraction intensity of the obtained X-ray diffraction pattern. If the FWHM of the peak exceeds a certain value, it can be determined that the crystallinity is low, and if not, it can be determined that the crystallinity is high.

In the ellipsometry, for example, the crystallinity is evaluated based on whether the rising angle of the absorption edge of the absorption coefficient exceeds a certain value from the obtained spectrum. If the rising angle of the absorption edge of the absorption coefficient exceeds a certain value, it is determined that the crystallinity is high, and if not, it can be determined that the crystallinity is low. In addition, if the obtained values, such as a refractive index n and an extinction coefficient k, are close to values known in advance as having high crystallinity, it is determined that the crystallinity is high, and if not, it is determined that the crystallinity is low.

In the electron backscatter diffraction, for example, the crystallinity is evaluated based on whether the average particle size exceeds a certain value from the obtained particle size distribution. If the average particle size exceeds a certain value, it can be determined that the crystallinity is high, and if not, it can be determined that the crystallinity is low.

In the Raman spectroscopy, for example, the crystallinity is evaluated based on whether the FWHM of a peak at a predetermined Raman shift exceeds a certain value from a relationship between the difference in frequency between the obtained incident and scattered light (Raman shift) and the intensity of the scattered light. If the FWHM of the peak exceeds a certain value, it can be determined that the crystallinity is low, and if not, it can be determined that the crystallinity is high.

In the electron diffraction, for example, the crystallinity is evaluated based on whether a predetermined electron diffraction pattern is obtained from the obtained electron diffraction pattern. If a predetermined diffraction pattern is obtained, it can be determined that the crystallinity is high, and if not, it can be determined that the crystallinity is low.

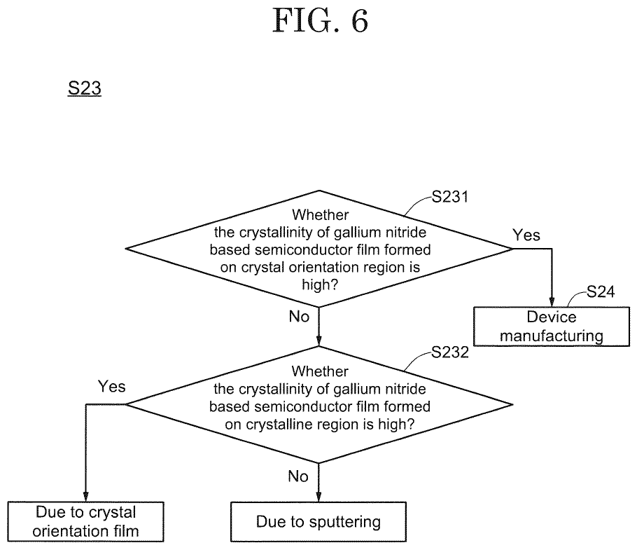

FIG. 6 is a flowchart showing the evaluation of the crystallinity of each of the formed gallium nitride based semiconductor films 113 (S23). As shown in FIG. 6, evaluating the crystallinity of each of the formed gallium nitride based semiconductor films 113 (S23) includes, in order, evaluating the crystallinity of the gallium nitride based semiconductor film 113 formed on the crystal orientation region 111 (S231) and evaluating the crystallinity of the gallium nitride based semiconductor film 113 formed on the crystalline region 112 (S232). In addition, before performing the crystallinity evaluation, the layered structure 1 may be cut and individualized for each gallium nitride based semiconductor film 113, and the crystallization evaluation may be performed to individualize only the gallium nitride based semiconductor film 113 with good crystallinity.

As shown in FIG. 6, first, the crystallinity of the gallium nitride based semiconductor film 113 formed on the crystal orientation region 111 is evaluated (S231). In the case where the crystallinity of the gallium nitride based semiconductor film 113 is high (Yes in S231), the gallium nitride based semiconductor film 113 formed on the layered structure 1 is used for manufacturing the gallium nitride based semiconductor device (S24). That is, the method 2 for inspecting a gallium nitride based semiconductor film according to an embodiment of the present invention can be configured as a part of a method for manufacturing a gallium nitride based semiconductor device.

In the step S231, when the crystallinity of the gallium nitride based semiconductor film 113 is not high (No in S231), the crystallinity of the gallium nitride based semiconductor film 113 formed on the crystalline region 112 is evaluated (S232). In the step S232, when the crystallinity of the gallium nitride based film 113 formed on the crystalline region 112 is high (Yes in S232), since the gallium nitride based semiconductor film 113 is satisfactorily formed in the crystalline region 112, it can be determined that the crystallinity of the gallium nitride based semiconductor film 113 formed on the crystal orientation region 111 is not high due to the crystal orientation film.

On the other hand, in the step S232, when the crystallinity of the gallium nitride based film 113 formed on the crystalline region 112 is not high (No in S232), since the crystallinity of the gallium nitride based semiconductor film 113 formed on the crystalline region 112 is high, as long as the sputtering is not defective, such as the material of the sputtering target and the deposition conditions, it can be determined that the crystallinity of the gallium nitride based semiconductor film 113 formed on the crystal orientation region 111 is not high due to the sputtering, such as the material of the sputtering target, the deposition conditions, and the like. Further, in the case of the sputtering, as factors thereof, for example, the material (composition, density, purity, etc.) of the sputtering target, the deposition conditions of sputtering (incorporation of impurities due to chamber leaks or residual gas in the chamber, abnormal discharge, insufficient pre-sputtering, fluctuations in deposition temperature, etc.), effects of pretreatment (effects of residual impurities due to poor cleaning, etc.) can be considered.

Further, it is understood that, even if the effect is different from those provided by the embodiments described above, the effect obvious from the description in the specification or easily predicted by persons ordinarily skilled in the art is apparently derived from the present invention.

What is claimed is:

1. A method for inspecting a gallium nitride based semiconductor film, comprising:
preparing a layered structure including a substrate and a crystal orientation region and a crystalline region disposed on the substrate;
forming a gallium nitride based semiconductor film on each of the crystal orientation region and the crystalline region; and
evaluating a crystallinity of each of the gallium nitride based semiconductor films formed on the crystal orientation region and the crystalline region.

2. The method according to claim 1,
wherein evaluating the crystallinity of each of the gallium nitride based semiconductor films includes, in order:
evaluating the crystallinity of the gallium nitride based semiconductor film formed on the crystal orientation region; and
evaluating the crystallinity of the gallium nitride based semiconductor film formed on the crystalline region.

3. The method according to claim 2,
wherein evaluating the crystallinity of each of the gallium nitride based semiconductor films is carried out by any one of X-ray diffraction, ellipsometry, electron backscatter diffraction, Raman spectroscopy, and electron diffraction.

4. The method according to claim 1,
wherein preparing the layered structure includes forming a crystal orientation film on the substrate to dispose the crystal orientation region on the substrate.

5. The method according to claim 4,
wherein preparing the layered structure includes bonding a crystalline substrate on the substrate to dispose the crystalline region on the substrate.

6. A method for manufacturing a gallium nitride based semiconductor device, comprising:
preparing a layered structure including a substrate and a crystal orientation region and a crystalline region disposed on the substrate;
forming a gallium nitride based semiconductor film on each of the crystal orientation region and the crystalline region; and
evaluating a crystallinity of each of the gallium nitride based semiconductor films formed on the crystal orientation region and the crystalline region.

7. The method according to claim 6,
wherein evaluating the crystallinity of each of the gallium nitride based semiconductor films includes, in order:
evaluating the crystallinity of the gallium nitride based semiconductor film formed on the crystal orientation region; and
evaluating the crystallinity of the gallium nitride based semiconductor film formed on the crystalline region.

8. The method according to claim 7,
wherein evaluating the crystallinity of each of the gallium nitride based semiconductor films is carried out by any one of X-ray diffraction, ellipsometry, electron backscatter diffraction, Raman spectroscopy, and electron diffraction.

9. The method according to claim 6,
wherein preparing the layered structure includes forming a crystal orientation film on the substrate to dispose the crystal orientation region on the substrate.

10. The method according to claim 9,
wherein preparing the layered structure includes bonding a crystalline substrate on the substrate to dispose the crystalline region on the substrate.

11. A layered structure comprising:
a substrate; and
a crystal orientation region and a crystalline region disposed on the substrate,
wherein a gallium nitride based semiconductor film is formed on each of the crystal orientation region and the crystalline region.

12. The layered structure according to claim 11, wherein a material of the crystal orientation region and a material of the crystalline region are the same.
